(19) United States
(12) Patent Application Publication
(10) Pub. No.: US 2025/0174453 A1
(43) Pub. Date: May 29, 2025

(54) A METHOD OF CLEANING A SEMICONDUCTOR SUBSTRATE FOR A SOLAR CELL, AND A CORRESPONDING CLEANING SYSTEM

(71) Applicant: REC Solar PTE. Ltd., Singapore (SG)

(72) Inventors: Chui Yu CHAN, Singapore (SG); Muzhi TANG, Singapore (SG)

(73) Assignee: REC Solar PTE. Ltd., Singapore (SG)

(21) Appl. No.: 18/725,572

(22) PCT Filed: Dec. 9, 2022
(86) PCT No.: PCT/EP2022/085157

§ 371 Date: Jun. 28, 2024

(30) Foreign Application Priority Data
Dec. 29, 2021 (GB) 2119067.3

(51) Int. Cl. H01L 21/02; H01L 21/67; H10F 71/00

(52) U.S. Cl. CPC H01L 21/02043; H01L 21/67034; H01L 21/67051; H10F 71/00

(57) ABSTRACT

A method of cleaning a semiconductor substrate for a solar cell, the method comprising: providing a semiconductor substrate; pre-oxidising the substrate with a pre-oxidising solution; oxidising the substrate with an oxidising solution to form an oxide on the surface of the substrate; removing the oxide from the surface of the substrate with an oxide removing solution; wherein the pre-oxidising solution is configured to remove metal ions from the surface of the substrate prior to the formation of the oxide on the substrate's surface, wherein the pre-oxidising solution is an acid solution comprising hydrogen chloride, and no other acid forming component.

### CROSS-REFERENCE TO RELATED APPLICATIONS

This application is a U.S. National Phase patent application based on International Patent Application No. PCT/EP2022/085157, filed Dec. 9, 2022; which claims priority to GB Patent Application No. 2119067.3, filed Dec. 29, 2021. The above referenced applications are incorporated herein by reference in their entirety as if fully set forth herein.

### FIELD OF THE DISCLOSURE

The present disclosure relates to a method of cleaning a semiconductor substrate for a solar cell, and a cleaning system for cleaning a semiconductor substrate for a solar cell.

### BACKGROUND

Solar modules for providing electrical energy from sunlight comprise an array of solar cells, each comprising a substrate, which is formed from a semiconductor material, such as silicon (e.g. a silicon wafer). Additional layers of semiconductor material are deposited onto the surfaces of the substrate to form the solar cell.

A general aim for solar cell development is to attain high conversion efficiency balanced by a need for reduced production costs. It is known that, despite careful fabrication procedures, the surfaces of semiconductor substrates can become contaminated with organic and/or metallic contaminants (e.g. dust, dirt, anions, cations, and other particles, etc.).

One way of improving the performance of the solar cell is to remove as much of the contamination from the substrate's surfaces as possible, before depositing the other semiconductor layers of the device. Efforts to achieve this have focussed on the cleaning of the semiconductor substrate using wet bench chemistry techniques and methodologies.

One approach to removing surface contaminants is to immerse the substrate in ‘ozonized water’, which has a very high oxidation potential that enables it to oxidatively degrade organic material. It is also known to use aqueous solutions containing hydrogen fluoride (i.e. HF acid) to remove contaminants by lifting off the thin native oxide in which the contaminants are embedded.

Despite these efforts, there remains a need to improve the methods of removing contaminants from the substrate's surfaces to increase the performance of the fabricated solar cell.

### SUMMARY

It is an object of the present invention to provide a method of cleaning a semiconductor substrate, such as a silicon wafer, to remove contaminants from the substrate's surfaces.

According to a first aspect of the invention there is provided a method of cleaning a semiconductor substrate for a solar cell, the method comprising: providing a semiconductor substrate; pre-oxidising the substrate with a pre-oxidising solution; oxidising the substrate with an oxidising solution to form an oxide on the surface of the substrate; removing the oxide from the surface of the substrate with an oxide removing solution; wherein the pre-oxidising solution is configured to remove metal ions from the surface of the substrate prior to the formation of the oxide on the substrate's surface, wherein the pre-oxidising solution is an acid solution comprising hydrogen chloride, and no other acid forming component.

It will be understood that the pre-oxidising method step defines a method (e.g. a procedure/process) which occurs prior to the oxidising method step. The pre-oxidising method step is not an oxidising method step, unlike the oxidising method step which is explicitly configured to oxidise the surface of the substrate. Accordingly, the pre-oxidising solution is not configured to oxidise the substrate's surface, unlike the oxidising solution.

It has been discovered that the invented process provides an enhanced method of cleaning semiconductor substrates. In particular, the pre-oxidising step is complimentary to the oxidation and oxide removing steps in removing contaminants from the substrate's surfaces. In particular, the pre-oxidising step is especially beneficial in removing contaminant metal ions which are deposited onto the substrate's surface during earlier cutting and texturing of the substrate.

The removal of metal ions from the surface of the substrate thereby reduces metallic contamination of the solutions used in the subsequent oxidation and oxide removal steps. As a result, the concentration of the hydrogen chloride in the subsequent oxidising solution and oxide removing solutions can be reduced.

In an exemplary method, at least one or each the oxidising and oxide removing solution(s) may comprise hydrogen chloride. In this situation, the presence of hydrogen chloride in the pre-oxidising solution means that the concentration of the hydrogen chloride in the other solutions can be reduced. Surprisingly, this means that the use of hydrogen chloride in the cleaning method, overall, can be reduced compared to cleaning methods which do not include a hydrochloric acid pre-oxidising step. Furthermore, the present invention means that all other acid forming components can be removed from the pre-oxidising method step (e.g., the pre-oxidising solution may be configured so that it does comprise any other acid forming component). In particular, the pre-oxidising solution may be configured so that it does not comprise hydrogen fluoride (HF). HF is very dangerous to humans and so its removal from the pre-oxidising method step, according to the present invention, may advantageously reduce the risk of causing harm or injury to a user of the substrate cleaning method.

In a further exemplary arrangement, the substrate may be intended for use in the fabrication of a solar cell. In this case, the present invention leads to an improvement in the performance of the solar cells which are fabricated using the substrates cleaned according to the above method. For example, substrates which have been cleaned by this method have been shown to produce solar cells that operate more efficiently than equivalent solar cells, which are produced using cleaning methods which don't include a pre-oxidising step.

In particular, the solar cells comprising substrates that have been cleaned according to the above method have been shown to exhibit an increased open circuit voltage (Voc), compared to devices which are fabricated with substrates that have been cleaned according to methods which do not include a pre-oxidising method step.

Optional features will now be set out. These are applicable singly or in any combination with any aspect.

Aspects of the description which follow are directed towards a semiconductor substrate which comprises a silicon material (e.g. a silicon wafer). However, it should be clearly understood that the invention is not limited to cleaning substrates made from silicon semiconductor materials. Any of the known semiconductor materials (e.g. germanium, etc.) having similar surface properties to silicon can also be cleaned by the described method.

The method may comprise providing a substrate with a textured surface. The textured surface may comprise a plurality of pyramid structures (e.g. comprising a plurality of upstanding or inverted pyramids structures). The textured surface may be the surface on which the oxide is formed and removed.

The method may comprise texturing the surface of the substrate (e.g. to form a plurality of pyramid structures). The surface texturing may be achieved by any suitable surface texturing method, including the use of photolithographic, mechanical (e.g. saws) and lasering techniques. Alternatively, the method of texturing the substrate's surface may comprise the use of a chemical etchant to selectively etch along particular crystallographic planes of the material from which the substrate is formed. It will be understood that such etching techniques are distinct from the pre-oxidising method step of the present invention because they require significant removal of material from the surface of the substrate. Whereas the pre-oxidising method step is advantageously configured to remove contaminants (e.g. metal ions) from the surface of the substrate.

The pre-oxidising solution defines an aqueous solution of hydrogen chloride (i.e. a hydrochloric acid solution). As such, it will be understood that the hydrogen chloride in the pre-oxidising solution is used as an acid forming component of the solution. This is because when hydrogen chloride is introduced to water, the respective HCl and H₂O molecules combine to form hydronium cations, H₃O+ (i.e. H+ ions), and chloride anions, Cl−, through a reversible chemical reaction. The pre-oxidising solution according to the present invention does not include any other substance, element, molecule, or component which could react with water to form dissociated cations and anions.

The duration of the pre-oxidising method step may be configured to be at least 50 seconds and up to 250 seconds.

The method step of pre-oxidising the substrate may comprise pre-cleaning the substrate with a pre-cleaning solution. The method step of pre-oxidising the substrate may comprise cleaning the substrate with a cleaning solution. The method step of pre-oxidising the substrate may comprise pre-cleaning the substrate with the pre-cleaning solution followed by cleaning the substrate with the cleaning solution. At least one, or each, of the pre-cleaning and cleaning solutions may comprise acid solutions containing hydrogen chloride, and no other acid forming component. Accordingly, the pre-cleaning and cleaning method steps may define first and second pre-oxidising method steps, respectively, and as such, the pre-cleaning and cleaning solutions may define first and second pre-oxidising solutions, respectively.

An exemplary method of the present invention may comprise: providing a semiconductor substrate; pre-cleaning the substrate with a pre-cleaning solution; cleaning the substrate with a cleaning solution; oxidising the substrate with an oxidising solution to form an oxide on the surface of the substrate; removing the oxide from the surface of the substrate with an oxide removing solution; wherein the pre-oxidising solution is configured to remove metal ions from the surface of the substrate prior to the formation of the oxide on the substrate's surface, wherein each of the pre-cleaning, cleaning, and pre-oxidising solutions are acid solutions comprising hydrogen chloride, and no other acid forming component.

The concentration of hydrogen chloride in the cleaning solution may be greater than the hydrogen chloride concentration of the pre-cleaning solution. The provision of a pre-cleaning solution with lower hydrogen chloride concentration reduces the cost of the cleaning process.

The pre-cleaning solution may comprise a hydrogen chloride concentration of at least 0.1 wt. % and/or up to 2.5 wt. %. In an alternative method, the hydrogen chloride concentration may be at least 0.4 wt. % and/or up to 2.0 wt. %. According to further alternative method, the hydrogen chloride concentration may be approximately 0.8 wt. % (e.g. 0.8 wt. %). The remainder of the solution may be made of water (e.g. deionised water).

The cleaning solution may comprise a hydrogen chloride concentration of at least 2.5 wt. % and/or up to 10 wt. %. In an alternative exemplary method, the hydrogen chloride concentration may be at least 3.0 wt. % and/or up to 7.0 wt. %. According to further alternative method, the hydrogen chloride concentration may be approximately 5.0 wt. % (e.g. 5 wt. %). The remainder of the solution may be made of water (e.g. deionised water).

It's considered that the increased concentration of hydrogen chloride in the cleaning solution leads to an abundance of H+ and Cl− ions, which induces a polarisation effect on the contaminants that are held on the substrate's surface by strong valence bonds. This polarisation effect overcomes the valence bonds and thereby remove the contaminants from the substrate's surface.

The duration of the pre-cleaning method step may be greater than the duration of the cleaning method step. Alternatively, duration of the pre-cleaning method step may be substantially the same as the other cleaning and/or rinsing steps, so as to prevent bottlenecks in the production.

The duration of the pre-cleaning method step may be configured to be at least 50 seconds and up to 250 seconds. The duration of the cleaning method step may be configured to be at least 50 seconds and up to 250 seconds.

The pre-cleaning solution may be at a temperature that is substantially equal to (e.g. equal to) or greater than the temperature of the cleaning solution. The cleaning solution may be at a temperature that is greater than the temperature of the pre-cleaning solution. The higher temperature of the pre-cleaning and/or cleaning solution(s) has the effect of increasing the speed of the respective pre-cleaning and/or cleaning steps.

The pre-cleaning solution may be heated to a temperature of at least 20° C. and/or up to 60° C. The cleaning solution may be at a temperature of at least 15° C. and/or up to 25° C. In an alternative exemplary method, the cleaning solution may be at a temperature of approximately 20° C. (e.g. 20° C.). Accordingly, the cleaning method may comprise not heating the cleaning solution, i.e. the cleaning solution may be maintained at room temperature.

It's considered that the increased temperature of the pre-cleaning step leads to an increased velocity of the H+ ions which can then migrate to the contaminants more quickly. The H+ ions can exchange themselves with the contaminants and thus attach themselves firmly to negatively ionized portions of the substrate's surface. If the sites where the migration occurs are negatively charged, then they become neutralized which frees the positively charged contaminants from the substrate's surface.

The oxidising solution may comprise an oxidising agent, or compound. The remainder of the oxidising solution may be made up with deionised water. The oxidising agent may be ozone (O₃) or hydrogen peroxide (H₂O₂). Accordingly, the oxidising solution may define an ozone containing solution. A purpose of the oxidising solution is to oxidise organic elements left behind from the additives used during the texturing of the substrate's surface (e.g. to form pyramid structures). Ozone has a very high oxidation potential that enables it to oxidatively degrade organic material. The ozone also oxidises the substrate's surface (i.e. the outer exposed surfaces of the pyramid structures).

The oxidising solution may comprise a hydrogen chloride concentration of at least 0.001 wt. % and/or up to 0.1 wt. %. In an alternative method, the hydrogen chloride concentration may be at least 0.005 wt. % and/or up to 0.05 wt. %. The remainder of the solution may be made of water (e.g. deionised water).

As described above, the pre-oxidising method step means that the hydrogen chloride concentration of the oxidising solution can be reduced. Advantageously, the hydrogen chloride concentration of the oxidising solution may be less than what is required for an equivalent method which doesn't include a pre-oxidising step (i.e. a method which does not subject the substrate to a pre-oxidising solution prior to oxidising the substrate's surface, as defined by the present invention).

The step of oxidising the substrate may comprise configuring the oxidising solution (i.e. the ozone containing solution) with hydrogen fluoride. The oxidising solution may comprise a hydrogen fluoride concentration of up to 0.03 wt. %. The hydrogen fluoride simultaneously removes the oxide which is formed on the substrate's surface by the oxidising agent in the oxidising solution.

The duration of the oxidising method step may be configured to be at least 50 seconds and up to 250 seconds. The duration of the oxide removing method step may be configured to be at least 50 seconds and up to 250 seconds.

The oxide removing solution may comprise a mixture of hydrogen fluoride and hydrogen chloride. The removing method step may comprise configuring the oxide removing solution with hydrogen fluoride, hydrogen chloride and deionised water. The hydrogen fluoride may be included with a concentration of at least 3 wt. % and/or up to 9 wt. %. The hydrogen chloride may be included with a concentration of at least 0.2 wt. % and/or up to 4 wt. %. The remainder of the solution may be made of water (e.g. deionised water).

The method may comprise directing a rinsing fluid at the substrate (e.g., immersing the substrate in a rinsing fluid). This may define a rinsing method step of the cleaning method. The rinsing fluid may be configured to remove from the substrate (e.g. the substrate's surface), any of the remaining active solution(s) (e.g. any one of the pre-oxidising (e.g. pre-cleaning and/or cleaning), oxidising, oxide removing solutions).

Accordingly, the rinsing method step may be configured to prevent chemical reactions from continuing after the substrate has been removed from the active solutions. The rinsing method step reduces contamination between the different active solutions. Also, the rinsing method step prevents contamination of the subsequent solar cell fabrication process.

The duration of the rinsing method step may be configured to be at least 50 seconds and up to 250 seconds.

The rinsing fluid may comprise a liquid (i.e. not a solid or gas). For example, the rinsing fluid may comprise water, such as deionised water. The rinsing fluid may be a uniform solution of deionised water (i.e. with substantially no other liquids or solid particles present in the solution). The rinsing fluid may be configured with a temperature of at least 15° C. and/or up to 25° C. In an alternative exemplary method, the rinsing fluid may be configured with a temperature of approximately 20° C. (e.g. 20° C.). Accordingly, the rinsing method step may comprise not heating the rinsing fluid, i.e. the rinsing solution may be configured to be maintained at room temperature.

The method may comprise a rinsing step (e.g., a further rinsing step) which is performed between the pre-oxidising and oxidising method steps. The method may comprise a rinsing step which is performed between the oxidising and removing method steps. At least one, or each, of the rinsing steps may be configured to remove excess, or residual, solutions (e.g. pre-cleaning solution, cleaning solution, pre-oxidising solution, oxidising solution, and/or oxide removing solution) from the substrate's surface to prevent cross contamination of the solutions.

The method may comprise a rinsing step (e.g., a further rinsing step) which is performed between the pre-cleaning and cleaning method steps. This rinsing step may comprise directing a rinsing fluid at the surface of the substrates to remove excess pre-cleaning solution from the substrate's surfaces, which thereby prevents contamination of the different solutions.

The, or each, rinsing step may comprise immersing (e.g., immersing and removing) the substrate in a container filled with rinsing fluid. Alternatively, the rinsing step may comprise directing (e.g. spraying) rinsing fluid at the substrate from a rinsing fluid dispensing assembly. The rinsing fluid dispensing assembly may be fluidly coupled (e.g. by a fluid conduit) to a source of rinsing fluid, such as pressurised pressure vessel. Alternatively, the rinsing fluid may be pumped to the fluid dispensing assembly by a controllable fluid pump, as would be understood by the skilled person.

The method may comprise directing a drying fluid at the substrate. This may define a drying method step of the cleaning method.

The drying fluid may be a liquid (e.g., water) or a vapour (e.g., nitrogen gas). The drying method step may comprise a liquid-drying method step which may involve directing a liquid-drying fluid at the substrate's surface. The liquid-drying method step may be carried out after the oxide removing method step and/or before a subsequent vapour-drying method step. The liquid-drying method step may comprise immersing the substrate in a container (e.g., tank) filled with rinsing fluid (e.g., a bath). The substrate may be immersed for a period of time (e.g., 50 to 250 seconds), before then removing (e.g., gradually removing) the substrate from the rinsing fluid. The liquid-drying fluid may comprise deionised water. The liquid-drying fluid may be provided at ambient room temperature (e.g., around 20° C.). The liquid-drying method step may be configured to partially dry the substrate and to give a substantially homogeneously wetted surface due to the slow removal of the substrate from the liquid-drying fluid.

The drying method step may comprise a vapour-drying method step (e.g., in which the drying-fluid is a vapour). The drying fluid (e.g., the vapour-drying fluid) may be configured to remove any remaining liquid from the substrate (e.g. pre-cleaning solution, cleaning solution, pre-oxidising solution, oxidising solution, oxide removing solution, rinsing fluid and/or liquid-drying fluid). The vapour-drying step reduces the residual liquid left on the substrate surfaces, which can otherwise attract particles and/or contaminants to the substrate. The drying fluid may be an inert gas, such as nitrogen gas. Alternatively, other suitable inert gases may be used, including Argon, for example.

The duration of the drying method step (e.g., the vapour-drying method step) may be configured to be at least 600 seconds and up to 800 seconds.

As part of the drying method step, the vapour (e.g., nitrogen gas) may be heated to a temperature of at least 50° C. and/or up to 90° C. The elevated temperature of the drying fluid increases the speed with which the substrate is dried, thereby reducing the overall duration of the cleaning method.

The vapour-drying method step may comprise directing (e.g. blowing) vapour-drying fluid at the substrate from a vapour-drying fluid dispensing assembly. The vapour-drying fluid dispensing assembly may be fluidly coupled (e.g. by a fluid conduit) to a source of drying fluid, such as pressurised pressure vessel. The flow of vapour-drying fluid may be controlled by a variable valve arranged along the fluid conduit between the vapour-drying fluid source and the vapour-drying fluid dispensing assembly, as would be understood by the skilled person.

At least one, or each, of the pre-oxidising, oxidising and oxide removing method steps may comprise the step of immersing the substrate into the respective solution(s). According to an alternative method at least one, or each, of the pre-oxidising (e.g. the pre-cleaning and/or cleaning), oxidising and oxide removing method steps may comprise the step of coating the substrate with a film of the associated solution(s) and then rotating the substrate to centrifugally remove the solution(s).

In exemplary methods, the pre-oxidising method step may comprise coating the substrate with a film of the pre-oxidising solution and then rotating the substrate to centrifugally remove the solution; and/or the oxidising method step may comprise coating the substrate with a film of the oxidising solution and then rotating the substrate to centrifugally remove the solution; and/or the removing step may comprise coating the substrate with a film of the oxide removing solution and then rotating the substrate to centrifugally remove the solution.

At least one of the pre-oxidising (e.g. the pre-cleaning and/or cleaning), oxidising and removing method steps may comprise immersing the substrate into the associated solution(s). In exemplary methods, the pre-oxidising method step may comprise immersing the substrate into the pre-oxidising solution, and/or the oxidising method step may comprise immersing the substrate into the oxidising solution; and/or the removing step may comprise immersing the substrate into the oxide removing solution.

The method may be applied to a batch immersion cleaning process, such as that which may be conducted using a wet bench cleaning system. In this situation, at least one or each of the method steps may be carried out using a plurality of containers (i.e. for holding the different solutions etc.). The substrate, or substrates, may be immersed in each of the solutions according to a pre-determined sequence of cleaning method steps.

Alternatively, two or more of the cleaning method steps may be carried out within a single container, whereby each of the solutions (e.g. pre-cleaning solution, cleaning solution, pre-oxidising solution, oxidising solution, and/or oxide removing solution) is directed (e.g. sprayed), in turn, onto the substrate, or substrates, according to the pre-determined sequence of cleaning method steps. For example, the method may be used in a single substrate cleaning process, such as that which may be carried out using a spin-coating cleaning system.

According to a second aspect of the invention there is provided a system for cleaning a semiconductor substrate for a solar cell, wherein the cleaning system is configured to clean the substrate according to the method of any one of the preceding statements.

According to a third aspect of the invention there is provided cleaning system for cleaning a semiconductor substrate for a solar cell, the system comprising: a pre-oxidiser configured to direct a pre-oxidising solution onto the substrate; an oxidiser configured to direct an oxidising solution onto the substrate to form an oxide on a surface of the substrate; an oxide remover configured to direct an oxide removing solution onto the substrate to remove the oxide from the surface of the substrate; wherein the pre-oxidising solution is configured to remove metal ions from the surface of the substrate prior to the formation of the oxide on the substrate's surface, wherein the pre-oxidising solution is an acid solution comprising hydrogen chloride, and no other acid forming component.

The pre-oxidiser may comprise a pre-cleaner configured to direct a pre-cleaning solution onto the substrate. The pre-oxidiser may comprise a cleaner configured to direct a cleaning solution onto the substrate. At least one, or each of, the pre-cleaning and cleaning solutions may comprise hydrogen chloride, and no other acid forming component.

At least one, or each, of the pre-oxidiser (e.g. the pre-cleaner and/or cleaner), oxidiser and oxide remover may comprise a container of a wet bench cleaning system. The container(s) may be configured to receive the substrate such that it can be immersed in the associated solution, as would be understood by the skilled person. The container(s) may be configured to receive a plurality of substrates at the same time, for example, if the plurality of substrates are supported by a substrate holder, or cradle.

At least one, or each, of the pre-oxidiser, oxidiser and oxide remover may comprise a component of a spin-coating cleaning system. For example, the oxidiser may comprise an outlet which is fluidly coupled to a storage vessel configured to hold a volume of pre-oxidising solution. A pump of the pre-oxidiser may be configured to direct pre-oxidising fluid from the storage vessel to the outlet and onto the substrate. The cleaning system may comprise a rotatable substrate support (or clamp) which is configured to rotate the substrate to centrifugally remove the pre-oxidising solution from the substrate's surface, as would be understood by the skilled person.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION OF THE DRAWINGS

Embodiments will now be described by way of example only, with reference to the Figures, in which:

FIGS. 1 to 6 are schematic views of a substrate cleaning system at different stages of a substrate cleaning method; and

FIG. 7 is a flowchart illustrating the method of cleaning a substrate, as shown in FIGS. 1 to 6.

### DETAILED DESCRIPTION

Aspects and embodiments of the present disclosure will now be discussed with reference to the accompanying figures. Further aspects and embodiments will be apparent to those skilled in the art.

FIGS. 1 to 6 show a substrate cleaning system 10 for cleaning a semiconductor substrate 20 according to an aspect of the present invention. The substrate 20 is formed of a semiconductor material, such as silicon. The substrate 20 is intended for use as a constituent component of a solar cell, as would be understood by the skilled person. The substrate 20 may comprise a silicon wafer, although it will be appreciated that the present cleaning method may be applied to other suitable semiconductor materials without departing from the scope of the present invention.

Prior to the substrate's use in the fabrication of a solar cell, its surfaces must be cleaned to remove any adhering particles and organic/inorganic impurities. Also, the native silicon oxide surface layer must be removed. Contaminants on the substrate's surfaces may be present as adsorbed ions and elements, thin films, discrete particles, particulates (e.g. particles), and adsorbed gases.

The cleaning system 10 comprises four containers 12, 14, 16, 18, or vessels, which are each configured to hold a liquid solution. A substrate 20 is submerged in each of the liquid solutions according to the cleaning method of the present invention. The system further comprises a drying assembly 50 which is configured to remove the liquid solutions from the substrate 20 and dry the substrate 20.

The cleaning system 10 also includes a rinsing assembly (not shown), which includes a rinsing tank containing a rinsing fluid (e.g., deionised water). The substrate 20 is received in the rinsing tank whereupon it is submerged in the rinsing fluid to remove any residual solution(s) from the substrate's surfaces. A separate rinsing assembly may be provided for use after each cleaning step, as will be appreciated by the skilled person.

The drying assembly 50 includes a liquid-drying tank 32 (e.g., a water-dryer), as shown in FIG. 5. The substrate 20 is received in the liquid-drying tank 32 whereupon it is submerged in the liquid-drying fluid 42 to remove any residual solution(s) from the substrate's surfaces. After being submerged in the liquid-drying fluid 42 for a period of time (e.g., between 50 and 250 seconds) the substrate 20 is slowly removed from the liquid-drying fluid 42 to partially dry the substrate 20 and to provide a substantially homogeneously wetted surface. The liquid-drying fluid 42 is deionised water, which is held at room temperature (e.g., around 20° C.). The liquid-drying fluid 42 is substantially the same as the rinsing fluid used in the rinsing assembly.

The drying assembly 50 also includes a drying tank 34 and a vapour-drying fluid dispensing outlet 38, or nozzle, as shown in FIG. 6. The substrate 20 is received in the drying tank 34 and a drying fluid 44 is directed (e.g. blown) from the dispensing outlet 38 towards the substrate's surfaces to remove any residual liquid and thereby dry the substrate 20. The drying assembly 50 is located at the bottom of the drying tank 34 with the fluid flow directed upwards and away from the substrate 20 through a drain 40 (e.g., fluid outlet), which is positioned at the top of the drying tank 34 to allow liquids to drain away.

Each of the containers 12, 14, 16, 18, the rinsing tank and the drying tanks 32, 34, are made from a chemically inert material such as polypropylene (PP) or polyvinylidene fluoride (PVDF). The containers which are configured to hold ozone may be, preferably, made from PVDF because it is more chemically inert. As such, the containers and rinsing/drying tanks are each configured not to react with the cleaning solutions which they may encounter during the cleaning process.

Each of the containers 12, 14, 16, 18 is provided with a heating system (not shown) which is configured to control the temperature of the liquid solution contained therein. The heating system comprises an electric resistance heating element, although it will be appreciated that other types heating system may also be used without departing from the scope of the present invention.

The heating system includes a temperature controller configured to regulate the operation of the heating element, and thereby adjust the temperature of the solution in the container. The temperature controller includes a temperature sensor (e.g. a thermocouple) configured to detect the temperature of the solution. The controller is configured to receive an input signal from the temperature sensor (e.g. indicative of the temperature of the liquid solution) and output a control signal (e.g. a current/voltage signal) to control the heating element to heat the container in dependence on the input signal. Accordingly, the controller can control the heating element to maintain the temperature of the solution at a pre-determined temperature, or within a range of temperatures, as required by the cleaning method.

The containers 12, 14, 16, 18 are dimensioned so that they can hold sufficient solution to allow the substrate 20 to be fully immersed (e.g. fully submerged). The rinsing tank and each of the drying tanks 32, 34 are all dimensioned so that they can receive the substrate 20 whilst also reducing the risk of any residual solution and/or rinsing/drying fluid from splashing out of the respective tanks.

With reference to FIG. 1, the first container 12 includes a pre-cleaning solution 22 (i.e. a first solution) comprising hydrogen chloride and deionised water. As such, the first container 12 defines a pre-cleaner of the cleaning system 10. The hydrogen chloride is included in the pre-cleaning solution 22 with a concentration of at least 0.4% and up to 2%, based on the weight of the solution. The temperature of the pre-cleaning solution 22 is configured to be at least 20° C. and up to 60° C. In an exemplary arrangement of the cleaning system 10, the pre-cleaning solution 22 is heated to a temperature of at least 30° C. and up to 45° C., optionally approximately 30° C. (e.g. 30° C.).

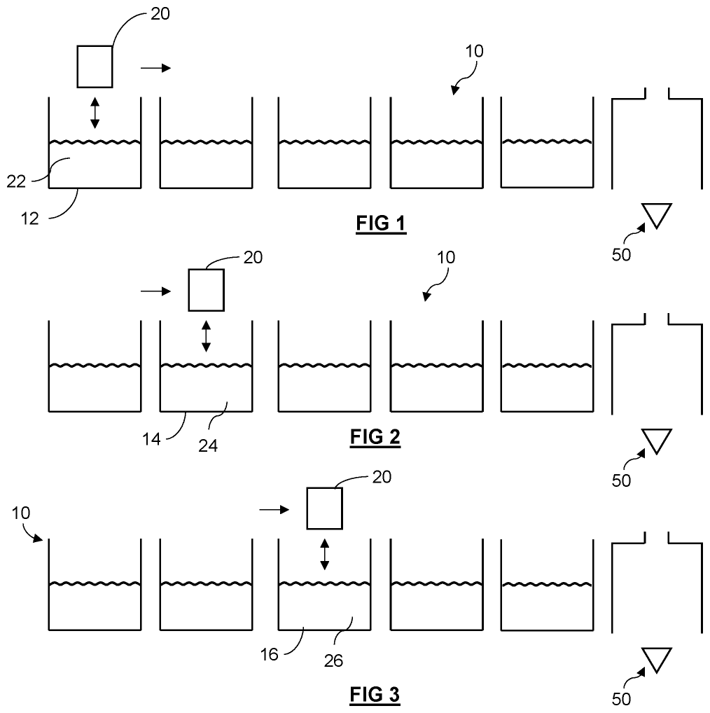

The second container 14 includes a cleaning solution 24 (i.e. a second solution) comprising hydrogen chloride and deionised water, as shown in FIG. 2. Accordingly, the second container 24 defines a cleaner of the cleaning system 10. The hydrogen chloride is included in the cleaning solution 24 with a concentration of at least 3% and up to 7%, based on the weight of the solution. The temperature of the cleaning solution 24 is controlled to be at room temperature (i.e. the ambient air temperature of the cleaning system's surroundings), such as approximately 20° C. (e.g. 20° C.).

Both the pre-cleaning and cleaning solutions 22, 24 define pre-oxidising solutions because, according to the cleaning method of the present invention, the substrate is immersed in each of the solutions prior to the substrate being oxidised by immersing it in an oxidising solution. Accordingly, the first and second containers 12, 14 each define pre-oxidisers of the cleaning system 10.

With reference to FIG. 3. the third container 16 includes an oxidising solution 26 (i.e. a third solution) comprising ozone, hydrogen fluoride, hydrogen chloride and deionised water. The hydrogen fluoride is included in the oxidising solution 26 with a concentration of at least 0% and up to 0.03%, based on the weight of the solution. The hydrogen chloride is included in the oxidising solution 26 with a concentration of at least 0.005% and up to 0.05%, based on the weight of the solution.

The ozone is included (i.e. dissolved) within the third solution 26 with a concentration of at least 1 and up to 100 ppm. In an alternative arrangement, the ozone concentration is configured to be up to 50 ppm, or alternatively up to 20 ppm. The ozone in the oxidising solution is configured to oxidise the surface of the substrate 20. Therefore, the third container 26 defines an oxidiser of the cleaning system 10.

The temperature of the oxidising solution 26 is configured to be at least 20° C. and up to 40° C. In an exemplary arrangement of the cleaning system 10, the oxidising solution 26 is heated to a temperature of at least 20° C. and up to 35° C., optionally approximately 23° C. (e.g. 23° C.).

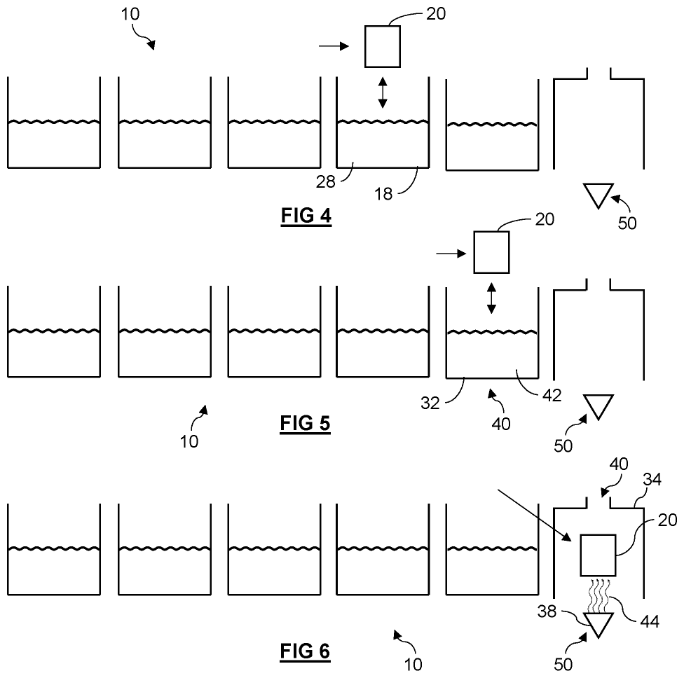

With reference to FIG. 4, the fourth container 18 includes an oxide removing solution 28 (i.e. a fourth solution) comprising hydrogen fluoride, hydrogen chloride and deionised water. The hydrogen fluoride is included in the oxide removing solution 28 with a concentration of at least 3% and up to 9%, based on the weight of the solution. The hydrogen chloride is included in the oxide removing solution 28 with a concentration of at least 0.2% and up to 4%, based on the weight of the solution. The temperature of the oxide removing solution 28 is controlled to be at room temperature.

The hydrogen fluoride in the oxide-removing solution 28 is configured to remove the oxide which is formed on the substrate's surface by the ozone in the oxidising solution 26. As such, the fourth container 28 defines an oxide remover of the cleaning system 10.

Each of the solutions 22, 24, 26, 28 is separately pre-mixed and stored in a suitable storage vessel. Each of the pre-mixed solutions 22, 24, 26, 28 is transferred directly from its storage vessel to the respective container 12, 14, 16, 18 prior to the start of the substrate cleaning process. Alternatively, each of the solutions can be mixed, in situ within the housing of the cleaning system, as would be understood by the skilled person. The solutions are formed using ultra-high purity semiconductor grade reagents, including a source of ultrapure water (e.g. deionised water).

The ozone is dissolved within the oxidising solution 26 by directing a flow of ozone containing gas (e.g. ozone gas, O₃) to the third container 16. The cleaning system 10 comprises a gas delivery apparatus (not shown) which is configured to supply the ozone containing gas from an ozone gas supply to the third container 16. The ozone gas is bubbled through the oxidising solution 26 as would be understood by the skilled person.

The ozone gas supply is an electrolytic ozone gas producing assembly, although any suitable supply of ozone gas may be used. For example, the supply of ozone gas is produced from an ozone generator which is fed with an oxygen (O₂) feed gas. The gas delivery apparatus is provided with a gas regulator (e.g. a controllable valve) which is configured to control the supply of ozone gas to the third container 16. This enables the ozone concentration in the third solution 26 to be adjusted precisely to a predetermined concentration, or concentration range, which can be maintained throughout the cleaning process.

The vapour-drying fluid dispensing outlet 38 of the drying assembly 50 is arranged to direct a flow of a vapour-drying fluid 44 towards the substrate 20 when it's arranged in the drying tank 34, as shown in FIG. 6. The vapour-drying fluid 44 is an inert gas, such as nitrogen gas. The vapour-drying fluid dispensing outlet 38 is fluidly coupled via a separate fluid conduit (not shown) to a source of nitrogen gas such as a pressurised gas storage vessel, or tank. The flow of the nitrogen gas to the outlet 38 is controlled by a variable valve (not shown) which thereby controls the flow of the gas being directed towards the substrate 20. The variable valve is configurable to only supply gas to the dispensing outlet 38 when the substrate 20 is positioned in the drying tank 34, as shown in FIG. 6.

The drying system 50 includes a drying assembly heating system which is configured to control the temperature of the drying fluid that is dispensed from the outlet 38. In particular, the heating system includes an electric resistance heating element which is conductively coupled to the gas conduit that supplies nitrogen gas to the second dispensing outlet 38. The heating element is operable to heat the nitrogen gas which flows through the conduit, as would be understood by the skilled person.

The drying assembly heating system includes a temperature controller as described above in relation to the cleaning fluid heating system. For example, the heating system includes a temperature sensor configured to determine the temperature of the gas being directed towards the substrate 20. A controller controls the operation of the heating element in dependence on the sensed gas temperature signals. In this way, the controller is configured to maintain the temperature of the nitrogen gas at a pre-determined temperature.

The drying assembly heating system is configured to heat the drying fluid 44 to a temperature of at least 50° C. and up to 90° C. In an exemplary arrangement of the cleaning system 10, the drying fluid 44 is heated to a temperature of at least 65° C. and up to 75° C., optionally approximately 70° C. (e.g. 70° C.).

In an alternative arrangement of the cleaning system 10, the drying assembly heating system is arranged to heat the drying tank 34 to control the temperature of the drying fluid 44. In this case, the drying tanks 34 is fitted with a heating element like that which is described above, in relation to the cleaning fluid heating system.

The containers 12, 14, 16, 18, the rinsing tank and the drying tanks 32, 34 each define a different cleaning station, or cleaning area, of the substrate cleaning system 10. The cleaning stations are all arranged within a housing (not shown) configured to prevent contamination of the substrate 20 and the cleaning apparatus. The housing is configured with a plurality of openings to allow access to a central interior volume of the housing in which the cleaning stations are arranged. The openings allow a user to move the substrate 20 between the different cleaning stations according to the cleaning method of the present invention.

The substrate 20 can be handled manually using a substrate tool such as a wafer handling wand, or a pair of tongs. Alternatively, the system 10 may comprise a substrate handling robot for holding and lifting the substrate 20 around within the housing. As such, the substrate handling robot may be arranged within the housing and configured to move the substrate 20 between the different cleaning stations. The use of such a robot allows the housing to be closed up during the cleaning method, which helps to reduce the risk of particles, and other airborne contaminants, from getting into the solutions 22, 24, 26, 28 and/or settling on the substrate's surfaces.

Whilst only a single substrate 20 in shown in FIGS. 1 to 6, it will be understood the cleaning system 10 may be configured such that a plurality of substrates 20 can be cleaned at the same time. The plurality of substrates 20 may be placed in a substrate carrier, or cradle, configured to support each of the substrates 20 in position whilst they are lifted between the different cleaning stations. It will be appreciated that each of the containers 12, 14, 16, 18, the rinsing tank and the drying tanks 32, 34 may be configured to receive the substrate carrier supporting the plurality of substrates 20.

The substrate carrier may also be formed of the same material as the containers (e.g. PTFE), as would be understood by the skilled person. The substrate carrier may be configured to support the substrates 20 so that they are spaced apart from each other, which allows the solutions to access the substrates' surfaces. As such, each of the substrates in the carrier is substantially aligned in parallel with the other substrates.

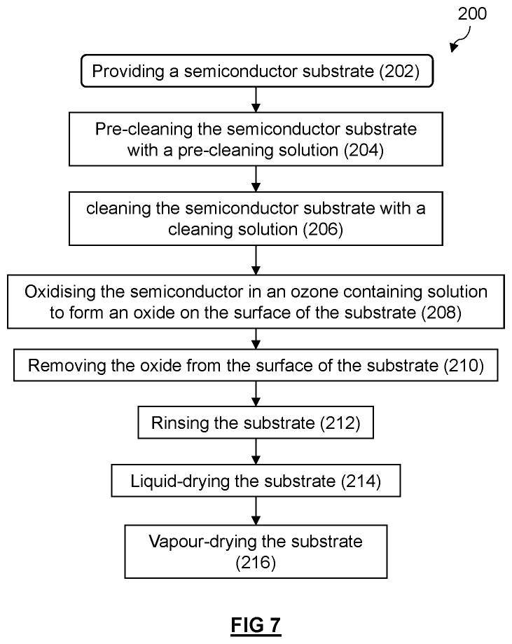

The substrate 20, or substrates, are moved between the different cleaning stations in a pre-determined sequence of the cleaning method 200 according to the present invention. The method of cleaning the substrate 20 will now be described with reference to the flow chart shown in FIG. 7, and with reference to cleaning system 10 shown in FIGS. 1 to 6.

The following description is directed towards a method of cleaning a single substrate. However, it will be appreciated that the same method steps could be applied equally to cleaning a plurality of substrates 20, without departing from the present invention.

The method commences with the first step 202 which involves providing the semiconductor substrate 20 to be cleaned. This first method step 202 also includes providing the solutions 22, 24, 26, 28, 42 in their respective containers 12, 14, 16, 18, 34 as shown in FIGS. 1 to 5. It further involves providing the drying assembly 50, as identified in FIGS. 5 and 6.

In a subsequent method step 204, the substrate is immersed in the pre-cleaning solution 22 for between 50 and 250 seconds (e.g., 215 seconds). As described above, the pre-cleaning solution 22 is an acid solution containing only hydrogen chloride and deionised water, with an acid concentration of at least 0.4% and up to 2%. As part of the method step 204, the acid solution is heated to a temperature of at least 20° C. and up to 60° C.

The cleaning method then proceeds with method step 204 which involves immersing the substrate 20 in the cleaning solution 24 for between 50 and 250 seconds (e.g., 215 seconds). The cleaning solution 24 is also an acid solution containing only hydrogen chloride and deionised water. The acid concentration of the cleaning solution 24 is at least 3% and up to 7%. The method step 206 does not include heating the cleaning solution 24, which is instead maintained at ambient room temperature.

In a further method step 208, the substrate is immersed in an oxidising solution 26 for between 50 and 250 seconds (e.g., 215 seconds). The oxidising solution 26 includes ozone, hydrogen fluoride, hydrogen chloride and deionised water, as described above. Method step 208 includes bubbling ozone gas through the oxidising solution 26 to form an ‘ozonized solution’. As part of method step 208, the third solution 26 is heated to a temperature of at least 20° C. and up to 40° C.

The purpose of this ozone cleaning is to oxidise organic elements left behind from the additives used during the texturing of the substrate's surface to form pyramid structures. The ozone also oxidises the substrate's surface (i.e. the surface of the pyramid structure).

The hydrogen fluoride in the oxidising solution 26 causes removal of the oxide which is being formed by the ozone. This process of concurrently removing the oxide which is simultaneously formed is referred to ‘rounding”. In an alternative exemplary method, the hydrogen fluoride is absent from the oxide removing solution 28 such that no rounding can take place during method step 208. In this situation, the oxide which is formed by the ozone is removed during the subsequent oxide removal step, as is described below.

The method then proceeds with method step 210, which involves immersing the substrate 20 in an oxide removing solution 28 for between 50 and 250 seconds. The oxide removing solution 28 includes hydrogen fluoride, hydrogen chloride and deionised water, as described above. The method step 210 does not include heating the oxide removing solution 28. Rather, the solution is maintained at ambient room temperature.

Following method step 210, the cleaning process proceeds with method step 212 in which the substrate 20 is moved to the rinsing tank (not shown), containing a rinsing fluid, so it can be rinsed for between 50 and 250 seconds. The rinsing method step 212 involves immersing/submerging the substrate 20 into the rinsing fluid to remove any residual solution(s) from the substrate's surfaces. This rinsing step may also be incorporated into each of the method steps 204, 206 and 208. Accordingly, the substrate 20 can be immersed in the rinsing fluid for a period (e.g. between 50 and 250 seconds) after it has been immersed in each of the pre-cleaning, cleaning and oxidising solutions 22, 24, 26. After each rinse, the substrate 20 proceeds with the next method step in the sequence.

The rinsing fluid (e.g. deionised water) is configured to rapidly halt any chemical reactions that are caused by the solutions 22, 24, 26, 28. The rinsing fluid also removes any chemical residues from the substrate 20, which could contaminate the other solutions.

The cleaning process continues with liquid-drying method step 214, which involves immersing the substrate 20 in liquid-drying fluid 42 (e.g., deionised water) contained in the liquid-drying tank 32, as shown in FIG. 5. Once the substrate 20 has been immersed in the liquid-drying fluid 42 for a period (e.g., between 50 and 250 seconds) it is slowly removed from the tank 32 to configure the substrate with homogenously wetted surfaces.

Each of the pre-cleaning, cleaning, oxidising, removing, rinsing method steps (e.g., the 204, 206, 208, 210, 212, 214) are carried out for the same duration, so as to not to cause a bottleneck in the cleaning process.

Once the substrate 20 has been rinsed (e.g., method step 212) and liquid-dried (e.g., method step 214) it is transferred, in method step 216, to the drying tank 34 whereupon it is dried for between 600 to 800 seconds with a rapid flow of vapour-drying fluid 44. Method step 216 also involves heating the vapour-drying fluid 44, and therefore the drying tank 34, to at least 50° C. and up to 90° C.

Once the cleaning method 200 has been completed for a first substrate 20 (or a first set of substrates), the method then returns to first method step 202 (e.g. with the provision of a further substrate 20, or set of substrates), before proceeding in the same order as described above.

The parameters for each of the pre-cleaning, cleaning, oxidising, removing, rinsing, and drying steps (204, 206, 208, 210, 212, 214, 216) are summarised in Table 1, below. The method steps 204, 206 precede the main oxidising and removing cleaning method steps 208 and 210, and as such they define pre-oxidising method steps of the cleaning method 200.

TABLE 1
Summary of parameters for the cleaning method 200

| | | HF conc. | HCl conc. | O₃ conc. | |
|---|---|---|---|---|---|
| Step | Solution | (wt. %) | (wt. %) | (ppm) | Temp. (° C.) |
| 204 | pre-cleaning sol. (22) | — | 0.4% to 2% | — | 20° C. to 60° C. |
| 206 | cleaning sol. (24) | — | 3% to 7% | — | Room Temp. |
| 208 | oxidising sol. (26) | 0% to 0.03% | 0.005% to 0.05% | 1 to 100 | 20° C. to 40° C. |
| 210 | oxide removing sol. (28) | 3% to 9% | 0.2% to 4% | — | Room Temp. |
| 212 | rinsing fluid | — | — | — | Room Temp. |
| 214 | liquid-drying fluid (42) | — | — | — | Room Temp. |
| 216 | vapour-drying fluid (44) | — | — | — | 50° C. to 90° C. |

It has been discovered that the invented process provides an enhanced method of cleaning semiconductor substrates 20. Each of the pre-cleaning and cleaning method steps 204, 206 (i.e. the pre-oxidising method steps) are configured to be complimentary to the oxidation and oxide removing steps 208, 210, to remove contaminants from the substrate's surfaces.

The pre-cleaning and cleaning solutions 22, 24 are configured to remove metal ions from the surface of the substrate 20, which thereby reduces metallic contamination of the solutions used in the subsequent oxidation and oxide removal method steps 208, 210 (i.e. the oxidising and oxide removing solutions 26, 28). As a result, the concentration of the hydrogen chloride in the oxidising and oxide removing solutions 26, 28 can be reduced. Surprisingly, this means that the total use of hydrogen chloride for the cleaning method 200 can be reduced compared to cleaning methods which do not comprise an acid pre-oxidising step.

The benefits of the present invention are also demonstrated by improvements in the performance characteristics of solar cells fabricated using substrates 20 which have been cleaned using the cleaning method 200. In particular, substrates which have been cleaned by this method have been shown to produce solar cells which operate more efficiently than solar cells which are produced using equivalent cleaning methods which do not include any pre-oxidising method step(s) (i.e. methods which do not comprise either the pre-cleaning or cleaning method steps 204, 206, as defined above).

The device parameters for a number of exemplary solar cell devices A, B, C, D and E are shown in Table 2, below. Each of the devices A to E are crystalline silicon heterojunction solar cells (HJT). Each of substrates for the devices A to E have undergone different cleaning processes, prior to fabricating the devices. The performance parameters shown in Table 2 have been normalised with respect to device A to show the relative differences in device performance. For example, each of the parameter values for devices B, C, D and E are shown as a percentage difference (+/−%) with respect to the corresponding parameter values of device A. As such, the parameter values of device A are all shown as 0.0%.

Devices A and B are made from substrates which have been cleaned according to a cleaning method which does not include a pre-oxidising method step are identified. The substrate of device A was cleaned for a total of 180 seconds, whereas the substrate of device B was cleaned for a total of 215 seconds.

The solar cells comprising substrates 20 which have been cleaned according to the cleaning method 200 of the present invention are identified as devices C, D and E in Table 2. The substrate of device C has been cleaned using an exemplary cleaning method of the present invention in which the cleaning step 206 is omitted (i.e. the method only involves the pre-cleaning method step 204). For this case, the total duration of the cleaning method 200 was 180 seconds.

The substrates used for devices D and E were both cleaned according to an exemplary method of the invention which includes the pre-cleaning, and the cleaning method steps 204, 206. The substrate of device D has been cleaned for a total of 180 seconds, whereas the substrate of device E has been cleaned for a total of 215 seconds.

For each of substrates used in devices A to E, the remaining method steps of the corresponding cleaning methods (e.g. the oxidising, oxide removing, rinsing, and drying steps) were substantially the same.

TABLE 2
Relative solar cell performance parameters for devices
A-E (normalised with respect to device A)

| | Relative | Relative | Relative | Relative |
|---|---|---|---|---|
| Method (duration - seconds) | CE (%) | I_{sc} (%) | V_{oc} (%) | FF (%) |
| A) No pre-oxidising (180) | 0.0% | 0.0% | 0.0% | 0.0% |
| B) No pre-oxidising (215) | −0.12% | −0.12% | 0.01% | −0.02% |
| C) pre-cleaning step only (180) | −0.08% | −0.09% | 0.07% | −0.06% |
| D) pre-cleaning and cleaning | −0.20% | −0.02% | 0.05% | −0.26% |
| steps (180) | | | | |
| E) pre-cleaning and cleaning | −0.20% | −0.06% | 0.08% | −0.22% |
| steps (215) | | | | |

With reference to Table 2, it is shown that the devices C, D and E (i.e. with substrates that were cleaned according to the method of the present invention) each exhibit an increased open circuit voltage (Voc) compared to devices A and B (i.e. with substrates that were cleaned according to a method which did not include a pre-oxidising method step).

The results in Table 2 show that the conversion efficiency (CE) and fill factor (FF) of solar cells C to E are slightly lower than for devices A and B. This was due to minor variations in the solar cell manufacturing process (e.g., cell printing).

In addition to the above, it is considered that the surprising and unexpected results of this invention rests with the simplicity of the methodology. For example, the method achieves enhanced cleaning of the semiconductor substrate without having to repeat any of the individual method steps. This means that the cleaning method can be completed quickly and with less contamination between the different solutions, which reduces waste. Accordingly, the cleaning method thereby reduces the overall substrate cleaning costs and improves the operating parameters of the resulting solar cell devices.

The above description outlines the cleaning method and cleaning system, according to the present invention, with certain concentrations of solutions, certain time periods for treatment, certain frequencies for immersing the substrates during treatment, certain time periods for rinsing and certain time periods for drying (e.g., liquid-drying and vapour-drying). However, the invention is not so limited. Various changes may be made whilst considering the degree of surface contamination, the size and quantity of the semiconductor substrates to be cleaned and the degree of cleanliness required. Additionally, the presently described method can be combined with other cleaning techniques.

The cleaning method as described above involves a batch immersion cleaning process, such as that which may be conducted using a wet bench cleaning setup. It will be appreciated, however, that the cleaning method 200 may comprise the use of alternative cleaning systems and apparatus, which may be configured to direct the same solutions 22, 24, 26, 28 at the substrate 20 according to the prescribed method.

For example, each of the method steps 204, 206, 208 and 210 (i.e. the pre-cleaning, cleaning, oxidising, and removing method steps) may be carried out using a spin-coating cleaning system. In this exemplary arrangement, the substrate 20 may be securely fixed to a rotating platform, with the substrate being arranged in a substantially horizontal orientation. A surface of the substrate is then coated with a film of the respective solution (e.g. the pre-cleaning, cleaning, oxidising or oxide-removing solution 22, 24, 26, 28) before rotating the substrate to centrifugally remove the solution from its surface. Similarly, the rinsing method steps and/or the liquid-drying method step may also be carried out using such a spin-coating cleaning system, as would be understood by the skilled person.

It will be understood that the invention is not limited to the embodiments above described and various modifications and improvements can be made without departing from the concepts described herein. Except where mutually exclusive, any of the features may be employed separately or in combination with any other features and the disclosure extends to and includes all combinations and sub-combinations of one or more features described herein.

### FEATURE LIST

Cleaning system 10
first, second, third and fourth containers 12, 14, 16, 18
Substrate 20
Pre-cleaning solution 22
Cleaning solution 24
Oxidising solution 26
Oxide removing solution solutions 28
Liquid-drying assembly 30
Liquid-drying tank 32
Vapour-drying tank 34
Fluid dispensing outlets 36, 38
Vapour-drying tank drain 40
Rinsing fluid 42
Drying fluid 44
Vapour-drying assembly 50
Cleaning method 200
Cleaning method steps 202, 204, 206, 208, 210, 212, 214 216

1. A method of cleaning a semiconductor substrate for a solar cell, the method comprising:
providing a semiconductor substrate;
pre-oxidising the substrate with a pre-oxidising solution;
oxidising the substrate with an oxidising solution to form an oxide on the surface of the substrate;
removing the oxide from the surface of the substrate with an oxide removing solution;
wherein the pre-oxidising solution is configured to remove metal ions from the surface of the substrate prior to the formation of the oxide on the substrate's surface, wherein the pre-oxidising solution is an acid solution comprising hydrogen chloride, and no other acid forming component.

2. The method according to claim 1, wherein the step of pre-oxidising the substrate comprises pre-cleaning the substrate with a pre-cleaning solution followed by cleaning the substrate with a cleaning solution; wherein each of the pre-cleaning and cleaning solutions are acid solutions containing hydrogen chloride, and no other acid forming component.

3. The method according to claim 2, wherein the concentration of hydrogen chloride in the cleaning solution is greater than in the pre-cleaning solution.

4. The method according to claim 2, wherein the pre-cleaning solution comprises a hydrogen chloride concentration of at least 0.1 wt. % and/or up to 2.5 wt. %, optionally at least 0.4 wt. % and/or up to 2.0 wt. %, further optionally 0.8 wt. %.

5. The method according to claim 2, wherein the cleaning solution comprises a hydrogen chloride concentration of at least 2.5 wt. % and/or up to 10 wt. %, optionally at least 3.0 wt. % and/or up to 7.0 wt. %, further optionally 5.0 wt. %.

6. The method according to claim 2, wherein the pre-cleaning solution is at a temperature that is substantially equal to or greater than the temperature of the cleaning solution.

7. The method according to claim 2, wherein the pre-cleaning solution is heated to a temperature of at least 20° C. and/or up to 60° C.

8. The method according to claim 2, wherein the cleaning solution is at a temperature of at least 15° C. and/or up to 25° C., optionally 20° C.

9. The method according to claim 2, wherein the method comprises a rinsing step between the pre-cleaning and cleaning steps, wherein the rinsing step comprises directing deionised water at the substrate.

10. The method according to claim 2, wherein the oxidising solution comprises a hydrogen chloride concentration of at least 0.001 wt. % and/or up to 0.1 wt. %, optionally at least 0.005 wt. % and/or up to 0.05 wt. %.

11. The method according to claim 1, wherein the method comprises directing a drying fluid at the substrate, the drying fluid being configured to remove remaining solution from the surface.

12. The method according to claim 11, wherein the drying fluid is an inert gas, optionally nitrogen gas.

13. The method according to claim 11, wherein the drying fluid is heated to a temperature of at least 50° C. and/or up to 90° C.

14. The method according to claim 11, wherein the method comprises a rinsing step prior to directing the drying fluid at the substrate, wherein the rinsing step comprises directing deionised water at the substrate.

15. The method according to claim 14, wherein the deionised water is at a temperature of at least 15° C. and/or up to 25° C., optionally 20° C.

16. The method according to claim 1, wherein the method comprises a rinsing step which is performed between the pre-oxidising and oxidising method steps and/or between the oxidising and removing method steps.

17. The method according to claim 1, wherein the step of oxidising the substrate comprises configuring the oxidising solution with hydrogen fluoride.

18. The method according to claim 17, wherein the oxidising solution comprises a hydrogen fluoride concentration of up to 0.03 wt. %.

19. The method according to claim 1, wherein at least one of the pre-oxidising, oxidising, and removing method steps comprises immersing the substrate into the associated solution.

20. The method according to claim 1, wherein at least one of the pre-oxidising, oxidising and removing method steps comprises coating the substrate with a film of the associated solution and rotating the substrate to centrifugally remove the solution.

21. A cleaning system for cleaning a semiconductor substrate for a solar cell, wherein the system is configured to clean the substrate according to claim 1.

22. A cleaning system for cleaning a semiconductor substrate for a solar cell, the system comprising:
a pre-oxidiser configured to direct a pre-oxidising solution onto the substrate;
an oxidiser configured to direct an oxidising solution onto the substrate to form an oxide on a surface of the substrate;
an oxide remover configured to direct an oxide removing solution onto the substrate to remove the oxide from the surface of the substrate;
wherein the pre-oxidising solution is configured to remove metal ions from the surface of the substrate prior to the formation of the oxide on the substrate's surface, wherein the pre-oxidising solution is an acid solution comprising hydrogen chloride, and no other acid forming component.
